(19) United States
(12) Patent Application Publication
(10) Pub. No.: US 2018/0275206 A1
(43) Pub. Date: Sep. 27, 2018

(54) PRECISION ADJUSTABILITY OF OPTICAL COMPONENTS IN A MAGNETOMETER SENSOR

(71) Applicant: Lockheed Martin Corporation, Bethesda, MD (US)

(72) Inventors: Joseph W. HAHN, Erial, NJ (US); Nicholas Mauriello Luzod, Seattle, WA (US); Wilbur Lew, Mount Laurel, NJ (US); Gregory Scott Bruce, Abington, PA (US)

(73) Assignee: Lockheed Martin Corporation, Bethesda, MD (US)

(21) Appl. No.: 15/468,303

(22) Filed: Mar. 24, 2017

(51) Int. Cl. G01R 33/032; G01J 1/58; G01J 1/04

(52) U.S. Cl. CPC G01R 33/032; G01J 1/0411; G01J 1/58

(57) ABSTRACT

A sensor is described comprising an assembly allowing for the adjustment of light through a plurality of lenses to magneto-optical defect center materials. In some implementations, an initial calibration is done on the sensor system to adjust the relative position of the optical excitation assembly to a base structure to benefit the final intended purpose of the sensor The optical excitation assembly for attachment to a base structure can be described as comprising a slot configured to adjust the optical excitation assembly in a respective linear direction relative to the base structure, an optical excitation source, a lens, and a drive screw mechanism. The drive screw mechanism can be configured to adjust a position of the lens relative to the optical excitation source.

### BACKGROUND

Magneto-optical defect center materials with defect centers can be used to sense an applied magnetic field by transmitting light into the materials and measuring the responsive light that is emitted. The defect centers in such materials are very small and extremely difficult to handle on a uniform or precision basis. The loss of light in such systems may be detrimental to measurements and operations. As a result, sensors lack sensitivity that can be achieved if such impediments are solved.

### SUMMARY

In order to adjust optical excitation through a plurality of lenses to magneto-optical defect center materials, the relative position of an optical excitation assembly material can be controlled. During manufacture of a sensor system, there may be small variations in how a magneto-optical defect center material is mounted or in the tolerances of sensor components including the lenses and spacers such that adjustment is needed after assembly to adjust and focus the generated optical excitation. In some implementations, the generated optical excitation is laser light from a laser diode. In some implementations, an initial calibration is done on the sensor system to adjust the relative position of the optical excitation assembly to a base structure to benefit the final intended purpose of the sensor.

In some implementations, an optical excitation assembly for attachment to a base structure may comprise a defect center in a magneto-optical defect center material in a fixed position relative to the base structure, a slot configured to adjust the optical excitation assembly in a respective linear direction relative to the base structure, an optical excitation source, a lens, and a drive screw mechanism. The drive screw mechanism can be configured to adjust a position of the lens relative to the optical excitation source. In some implementations, the optical excitation assembly can further include a plurality of drive screw mechanisms, where the plurality of drive screw mechanisms are configured to adjust a position of the lens relative to the optical excitation source. In some implementations, each of the plurality of drive screw mechanisms may be configured to adjust in a direction orthogonal to the other drive screw mechanisms.

In some implementations, the optical excitation assembly can further comprise a shim configured to adjust the optical excitation assembly in a linear direction relative to the base structure. In some implementations, the optical excitation assembly can further comprise a magneto-optical defect center material with defect centers. The light from the optical excitation source can be directed through the lens into the magneto-optical defect center material with defect centers.

In some implementations, the optical excitation assembly can further comprise a half-wave plate assembly. The half-wave plate assembly can comprise a half-wave plate, a mounting disk adhered to the half-wave plate, and a mounting base configured such that the mounting disk can rotate relative to the mounting base around an axis of the half-wave plate. In some implementations, the lens can be configured to direct light from the optical excitation source through the half-wave plate before the light is directed to the magneto-optical defect center material. In some implementations, the optical excitation assembly can further comprise a pin adhered to the mounting disk. The mounting base can comprise a mounting slot configured to receive the pin. The pin can slide along the mounting slot and the mounting disk can rotate relative to the mounting base around the axis of the half-wave plate, with the axis perpendicular to a length of the mounting slot.

In some implementations of the optical excitation assembly, the magneto-optical defect center material with defect centers may comprise a nitrogen vacancy (NV) diamond material comprising a plurality of NV centers.

In some implementations of the optical excitation assembly, the optical excitation assembly may further comprise a screw lock inserted through the slot and configured to prevent relative motion of the optical excitation assembly to the base structure when tightened.

In some implementations, an assembly for attachment to a base structure is described. The assembly can comprise a slot configured to adjust the assembly in a respective linear direction relative to the base structure, an optical excitation source, a plurality of lenses, an adjustment mechanism, and a magneto-optical defect center material with defect centers. The adjustment mechanism can be configured to adjust a position of the plurality of lenses relative to the optical excitation source. The light from the optical excitation source can be directed through the plurality of lenses into the magneto-optical defect center material with defect centers. In some implementations, the assembly can be configured to direct light from the optical excitation source through a half-wave plate before the light is directed to the magneto-optical defect center material.

In some implementations, the assembly can further comprise a mounting disk adhered to the half-wave plate. The mounting disk can be configured to rotate relative to the mounting base around the axis of the half-wave plate. In some implementations, the assembly can further comprise a pin adhered to the mounting disk. The mounting base can comprise a mounting slot configured to receive the pin. The pin can slide along the slot and the mounting disk can rotate relative to the mounting base around the axis of the half-wave plate, the axis perpendicular to a length of the slot.

In some implementations of the assembly, the magneto-optical defect center material with defect centers may comprise a nitrogen vacancy (NV) diamond material comprising a plurality of NV centers. In some implementations, the optical excitation source is one of a laser diode or a light emitting diode.

In some implementations, the assembly may further comprise a screw lock inserted through the slot. The screw lock can be configured to prevent relative motion of the optical excitation assembly to the base structure when tightened. A second screw lock attached to the mounting disk can be configured to prevent rotation of the mounting disk relative to the mounting base when tightened.

In some implementations, the lens of the assembly can be configured to direct light from the optical excitation source through the half-wave plate before the light is directed to the magneto-optical defect center material.

In some implementations, a sensor assembly may comprise a base structure and an optical excitation assembly. The optical excitation assembly can comprise an optical excitation means, for providing optical excitation through a plurality of lenses, magneto-optical defect center material comprising a plurality of magneto-optical defect centers, and an adjustment means, for adjusting the location of the provided optical excitation where it reaches the magneto-optical defect center material.

In some implementations, a method of adjusting an optical excitation assembly relative to a base structure may comprise, adjusting an optical excitation source in a respective linear direction relative to the base structure using a slot and adjusting a position of a lens in the optical excitation assembly relative to the optical excitation source using a drive screw mechanism. The adjusting the optical excitation source and adjusting the position of a lens may direct light from the optical excitation source to a defect center in a magneto-optical defect center that is in a fixed position relative to the base structure.

In some implementations, the method may further comprise adjusting the position of the lens in the optical excitation assembly using a plurality of drive screw mechanisms. Each of the plurality of drive screw mechanisms may adjust in a direction orthogonal to the other drive screw mechanisms. In some implementations, the method may further comprise adjusting the optical excitation assembly in a linear direction relative to the base structure using a shim. In some implementations, the method may direct the light from the optical excitation source through the lens to the defect center.

In some implementations, the method may further comprise rotating a half-wave plate attached to the optical excitation assembly around an axis of the half-wave plate using a half-wave plate assembly. The half-wave plate assembly may comprise a mounting disk adhered to the half-wave plate. In some implementations, the method may further comprise sliding a pin adhered to the mounting disk along a mounting slot in the mounting disk, the axis of the half-wave plate perpendicular to a length of the mounting slot when rotating the half-wave plate. In some implementations, the method further comprises tightening a screw lock inserted through the slot to prevent relative motion of the optical excitation assembly to the base structure. In some implementations, the magneto-optical defect center material with the defect center comprises a nitrogen vacancy (NV) diamond material comprising a plurality of NV centers.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

FIG. 1 illustrates an optical excitation assembly with adjustable spacing features in accordance with some illustrative embodiments.

FIG. 2 illustrates a cross section as viewed from above of a portion of the optical excitation assembly in accordance with some illustrative embodiments.

FIG. 3 is a schematic diagram illustrating a NV center magnetic sensor system with half wave plate in accordance with some illustrative embodiments.

FIG. 4 illustrates an NV center in a diamond lattice in accordance with some illustrative embodiments.

FIG. 5 illustrates an energy level diagram showing energy levels of spin states for an NV center in accordance with some illustrative embodiments.

FIG. 6 is a graph illustrating the fluorescence as a function of an applied RF frequency of an NV center along a given direction for a zero magnetic field in accordance with some illustrative embodiments.

FIG. 7 is a graph illustrating the fluorescence as a function of an applied RF frequency for four different NV center orientations for a non-zero magnetic field in accordance with some illustrative embodiments.

The foregoing and other features of the present disclosure will become apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Magneto-optical defect center materials such as diamonds with nitrogen vacancy (NV) centers can be used to detect magnetic fields. Atomic-sized nitrogen-vacancy (NV) centers in diamond lattices can have excellent sensitivity for magnetic field measurement and enable fabrication of small magnetic sensors that can readily replace existing-technology (e.g., Hall-effect, SERF, or SQUID) systems and devices. The sensing capabilities of diamond NV (DNV) sensors may be maintained in room temperature and atmospheric pressure and these sensors can be even used in liquid environments.

Green light which enters a diamond structure with NV centers interacts with NV centers, and red light is emitted from the diamond. The amount of red light emitted can be used to determine the strength of the magnetic field. The efficiency and accuracy of sensors using magneto-optical defect center materials such as diamonds with NV centers (generally, DNV sensors) is increased by transferring as much light as possible from the NV centers to the photo sensor that measures the amount of red light. Magneto-optical defect center materials include but are not be limited to diamonds, Silicon Carbide (SiC) and other materials with nitrogen, boron, or other chemical defect centers.

In some implementations, the optics of the components is made adjustable to allow for the proper placement of electromagnetic radiation directed to a magneto-optical defect center material. In some implementations a half-wave plate is mounted to be rotatable to allow for changing the polarization of the entering laser light. In some implementations, the half-wave plate is locked into a location at a desired rotation and a corresponding polarization. In some implementations the polarization is aligned sequentially to obtain the improved (e.g., best) performance for each alignment to an axis of the magneto-optical defect center material. In some implementations, the polarization is aligned to obtain increased performance for each alignment to a crystal lattice of the magnet-optical defect center. In some implementations a plurality of half-wave plates is used corresponding to a plurality of the axis of the magneto-optical defect center to obtain increased performance all at once rather than sequentially.

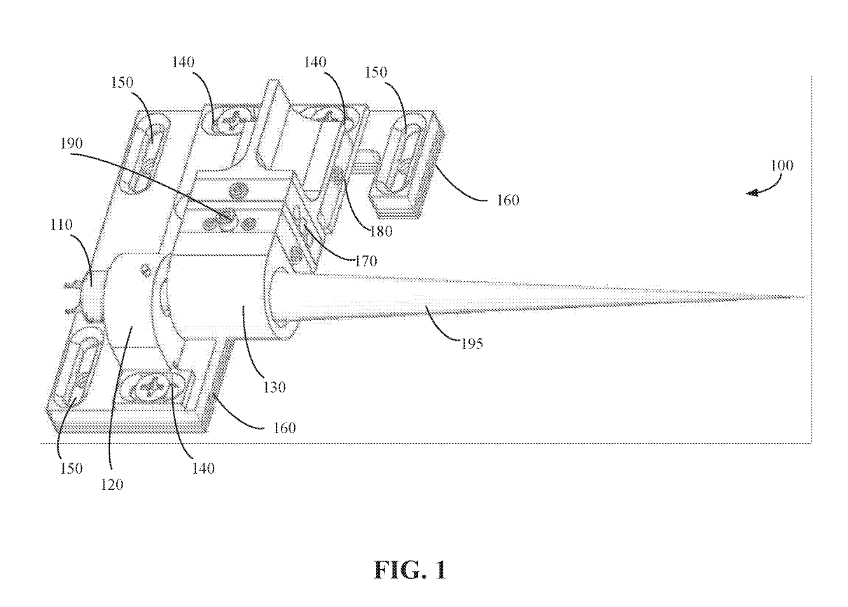

FIG. 1 illustrates an optical excitation assembly 100 with adjustable spacing features in accordance with some illustrative embodiments. The optical excitation assembly 100 includes, in brief, an optical excitation module 110 (e.g., a laser diode), an optical excitation module mount 120, a lens mount 130, one or more X axis translation slots 140, one or more y axis translation slots 150, Z axis translation material 160 (e.g., shims), an X axis lens translation mechanism 170, and a Y axis lens translation mechanism 180. In addition, FIG. 1 comprises an illustration of a representation of a light beam 195.

Still referring to FIG. 1 and in further detail, the optical excitation assembly 100 comprises an optical excitation module 110. In some implementations, the optical excitation module 110 is a directed light source. In some implementations, the optical excitation module 110 is a light emitting diode. In some implementations, the optical excitation module 110 is a laser diode. In some implementations, the optical excitation assembly 100 comprises an optical excitation module mount 120 that is configured to fasten the optical excitation module 110 in position relative to the rest of the optical excitation assembly 100.

In some implementations, the optical excitation assembly 100 further comprises a lens mount 130. In some implementations, the lens mount 130 is configured to fasten a plurality of lenses in position relative to each respective lens as well as configured to fasten a plurality of lenses in position relative to the rest of the optical excitation assembly 100.

In some implementations, the optical excitation assembly 100 further comprises one or more X axis translation slots 140. The one or more X axis translation slots 140 can be configured to allow for a positive or negative adjustment of the optical excitation assembly 100 in a linear direction. In some implementations, the linear direction is orthogonal to a path of a light beam 195 generated by the optical excitation assembly 100. In some implementations, the X axis translation slots 140 are configured to, upon adjustment, be used to fasten the optical excitation assembly 100 to an underlying mount. In some implementations, the X axis translations slots 140 are configured to accept a screw or other fastener that can be tightened to an underlying mount to fasten the optical excitation assembly 100 to an underlying mount in a fixed location. In some implementations, the X axis translations slots 140 are used to align the path of a light beam 195 to a desired target destination.

In some implementations, the optical excitation assembly 100 further comprises one or more Y axis translation slots 150. The one or more Y axis translation slots 150 can be configured to allow for a positive or negative adjustment of the optical excitation assembly 100 in a linear direction. In some implementations, the linear direction is parallel to a path of a light beam 195 generated by the optical excitation assembly 100. In some implementations the linear direction is orthogonal to the linear direction of the one or more X axis translation slots 140. In some implementations, the Y axis translation slots 150 are configured to, upon adjustment, be used to fasten the optical excitation assembly 100 to an underlying mount. In some implementations, the Y axis translations slots 150 are configured to accept a screw or other fastener that can be tightened to an underlying mount to fasten the optical excitation assembly 100 to an underlying mount in a fixed location. In some implementations, the Y axis translations slots 150 are used to adjust the distance of the path of a light beam 195 from a desired target destination.

In some implementations, the optical excitation assembly 100 further comprises Z axis translation material 160. In some implementations, the Z axis translation material 160 comprises one or more shims. In some implementations the Z axis translation material 160 can be added to or removed from the optical excitation assembly 100 for a positive or negative adjustment of the optical excitation assembly 100 in a linear direction relative to an underlying mount to which the optical excitation assembly 100 is fastened. In some implementations, the linear direction is orthogonal to two or more of the linear direction of the one or more X axis translation slots 140, the linear direction of the one or more Y axis translations slots 150, and/or the path of a light beam 195 generated by the optical excitation assembly 100. In some implementations the linear direction is orthogonal to the linear direction of the one or more X axis translation slots 140. In some implementations, the Z axis translation material 160 is configured to, upon adjustment, be used to alter a distance of the fastening of the optical excitation assembly 100 to an underlying mount. In some implementations, the Z axis translation material 160 is configured to accommodate the one or more X axis translation slots 140 and/or the one or more Y axis translations slots 150 with similar or matching slots in the Z axis translation material 160 in order to accept a plurality of screws or other fasteners that can be tightened to an underlying mount to fasten the optical excitation assembly 100 to the underlying mount in a fixed location. In some implementations, the Z axis translation material 160 are used to adjust the path of a light beam 195 to a desired target destination.

In some implementations, the optical excitation assembly 100 further comprises an X axis lens translation mechanism 170. The X axis lens translation mechanism 170 can be configured to allow for a positive or negative adjustment of the one or more lenses in a lens mount 130 in a linear direction. In some implementations, the linear direction is parallel to a path of a light beam 195 generated by the optical excitation assembly 100. In some implementations, the X axis lens translation mechanism 170 is used to align a lens to a path of a light beam 195. In some implementations, the X axis lens translation mechanism 170 is a drive screw mechanism configured to move the one or more lenses in a lens mount 130 in the linear direction.

In some implementations, the optical excitation assembly 100 further comprises a Y axis lens translation mechanism 180. The Y axis lens translation mechanism 180 can be configured to allow for a positive or negative adjustment of the one or more lenses in a lens mount 130 in a linear direction. In some implementations, the linear direction is orthogonal to a path of a light beam 195 generated by the optical excitation assembly 100. In some implementations, the Y axis lens translations mechanism 180 is used to align a lens to a path of a light beam 195. In some implementations, the Y axis lens translation mechanism 180 is a drive screw mechanism configured to move the one or more lenses in a lens mount 130 in the linear direction.

In some implementations, the optical excitation assembly 100 further comprises a Z axis lens translation mechanism 190. The Z axis lens translation mechanism 190 can be configured to allow for a positive or negative adjustment of the one or more lenses in a lens mount 130 in a linear direction. In some implementations, the linear direction is orthogonal to a path of a light beam 195 generated by the optical excitation assembly 100. In some implementations, the linear direction is orthogonal to a path of a light beam 195 generated by the optical excitation assembly 100 and to one or more of the linear adjustment of the X axis lens translation mechanism 170 or the Y axis lens translation mechanism 180. In some implementations, the Z axis lens translations mechanism 180 is used to align a lens to a path of a light beam 195. In some implementations, the Z axis lens translation mechanism 190 is a drive screw mechanism configured to move the one or more lenses in a lens mount 130 in the linear direction.

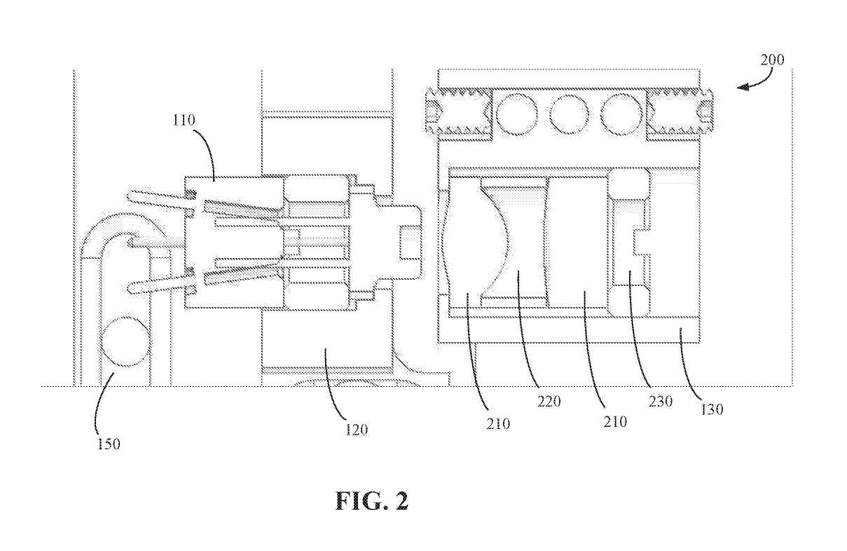

FIG. 2 illustrates a cross section as viewed from above of a portion of the optical excitation assembly 100 in accordance with some illustrative embodiments. The optical assembly cross section 200 includes, in brief, an optical excitation module 110 (e.g., a laser diode), an optical excitation module mount 120, a lens mount 130, one or more y axis translation slots 150, one or more lenses 210, a lens spacer 220, and a lens retaining ring 230.

Still referring to FIG. 2 and in further detail, the optical assembly cross section 200 comprises an optical excitation module 110. In some implementations, the optical excitation module 110 is a directed light source. In some implementations, the optical excitation module 110 is a light emitting diode. In some implementations, the optical excitation module 110 is a laser diode. In some implementations, the optical assembly cross section 200 comprises an optical excitation module mount 120 that is configured to fasten the optical excitation module 110 in position relative to the rest of the optical assembly cross section 200.

In some implementations, the optical assembly cross section 200 further comprises a lens mount 130. In some implementations, the lens mount 130 is configured to fasten a plurality of lenses 210 in position relative to each respective lens 210 as well as configured to fasten a plurality of lenses 210 in position relative to the rest of the optical assembly cross section 200. In some implementations, a lens spacer 220 is configured to maintain a fixed distance between one or more lenses 210. In some implementations, a lens retaining ring 230 is configured to hold one or more lenses 210 in a proper position relative to the lens mount 130.

In some implementations, the optical assembly cross section 200 further comprises one or more Y axis translation slots 150. The one or more Y axis translation slots 150 can be configured to allow for a positive or negative adjustment of the optical assembly cross section 200 in a linear direction. In some implementations, the linear direction is parallel to a path of a light beam generated by the optical assembly cross section 200. In some implementations the linear direction is orthogonal to the linear direction of the one or more X axis translation slots 140. In some implementations, the Y axis translation slots 150 are configured to, upon adjustment, be used to fasten the optical excitation assembly 100 to an underlying mount. In some implementations, the Y axis translations slots 150 are configured to accept a screw or other fastener that can be tightened to an underlying mount to fasten the optical assembly cross section 200 to an underlying mount in a fixed location. In some implementations, the Y axis translations slots 150 are used to adjust the distance of the path of a light beam from a desired target destination.

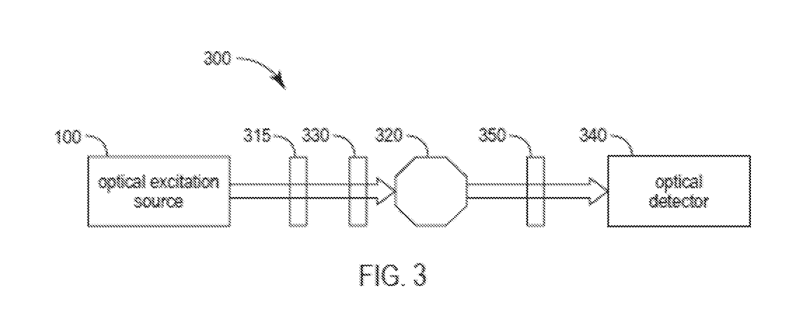

FIG. 3 is a schematic diagram illustrating a conventional NV center magnetic sensor system 300 that uses fluorescence intensity to distinguish the mₛ=±1 states, and to measure the magnetic field based on the energy difference between the mₛ=+1 state and the mₛ=−1 state. The system 300 includes an optical excitation source 100, which directs optical excitation through a half-wave plate 315 to a magneto-optical defect center material 320 with defect centers (e.g, NV diamond material). The system further includes an RF excitation source 330, which provides RF radiation to the magneto-optical defect center material 320. Light from the NV diamond may be directed through an optical filter 350 to an optical detector 340.

In some implementations, the RF excitation source 330 may be a microwave coil. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

In some implementations, the optical excitation source 100 may comprise a laser or a light emitting diode which emits light in the green. In some implementations, the optical excitation source 100 induces fluorescence in the red, which corresponds to an electronic transition from the excited state to the ground state. In some implementations, the light from the optical excitation source 100 is directed through a half-wave plate 315. In some implementations, light from the magneto-optical defect center material 320 is directed through the optical filter 350 to filter out light in the excitation band (in the green, for example), and to pass light in the red fluorescence band, which in turn is detected by the detector 340. The optical excitation light source 100, in addition to exciting fluorescence in the diamond material 320, also serves to reset the population of the mₛ=0 spin state of the ground state ³A₂ to a maximum polarization, or other desired polarization.

In some implementations, the light is directed through a half-wave plate 315. In some implementations, the half-wave plate 315 is in a shape analogous to a cylinder solid with an axis, height, and a base. In some implementations, the performance of the system is affected by the polarization of the light (e.g., light from a laser) as it is lined up with a crystal structure of the magneto-optical defect center material 320. In some implementations, a half-wave plate 315 is mounted to allow for rotation of the half-wave plate 315 with the ability to stop and/or lock the half-wave plate 315 into position at a specific rotation. This allows the tuning of the polarization relative to the magneto-optical defect center material 320. Affecting the performance of the system allows for the affecting of the responsive Lorentzian curves (or Lorentzians). In some implementations, when a laser polarization is lined up with the orientation of a given lattice of the magneto-optical defect center material 320, the contrast of the dimming Lorentzian, the portion of the light sensitive to magnetic fields, is deepest and narrowest such that the slope of each side of the Lorentzian is steepest. In some implementations, a laser polarization lined up with the orientation of a given lattice of the magneto-optical defect center material 320 allows extraction of maximum sensitivity of the lattice (i.e., maximum sensitivity of a BCO vector in free space. In some implementations, four positions of the half-wave plate 315 are determined to maximize the sensitivity to different lattices of the magneto-optical defect center material 320. In some implementations, a position of the half-wave plate 315 is determined to get similar sensitivities or contrasts to the four Lorentzians corresponding to lattices of the magneto-optical defect center material 320.

In some implementations, a position of the half-wave plate 315 is determined as an initial calibration for a light directed through a half-wave plate 315. In some implementations, the performance of the system is affected by the polarization of the light (e.g., light from a laser) as it is lined up with a crystal structure of the magneto-optical defect center material 320. In some implementations, a half-wave plate 315 is mounted to allow for rotation of the half-wave plate 315 with the ability to stop and/or lock the half-wave after an initial calibration determines the eight Lorentzians associated with a given lattice with each pair of Lorentzians associated with a given lattice plane symmetric around the carrier frequency. In some implementations, the initial calibration is set to allow for high contrast with steep Lorentzians for a particular lattice plane. In some implementations, the initial calibration is set to create similar contrast and steepness of the Lorentzians for each of the four lattice planes.

In various embodiments described herein, the material with the defect centers may be formed in a shape that directs light from the defect centers towards the photo diode. When excited by the green light photon, an defect center emits a red light photon. But, the direction that the red light photon is emitted from the defect center is not necessarily the direction that the green light photon was received. Rather, the red light photon can be emitted in any direction or all directions. In some implementations the sides of the magneto-optical defect center materials are angled and polished to reflect red light photons towards the photo sensor.

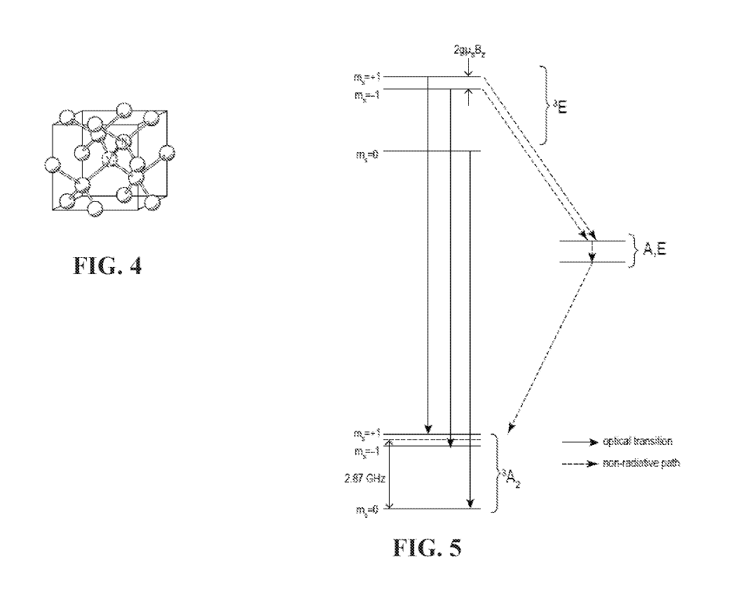

In some implementations, the magneto-optical defect center material is a diamond where the NV center in the diamond comprises a substitutional nitrogen or boron atom in a lattice site adjacent a carbon vacancy as shown in FIG. 4. The NV center may have four orientations, each corresponding to a different crystallographic orientation of the diamond lattice.

The NV center may exist in a neutral charge state or a negative charge state. Conventionally, the neutral charge state uses the nomenclature NV₀, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 5, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of 2.87 GHz for a zero external magnetic field.

Introducing an external magnetic field with a component along the NV axis lifts the degeneracy of the mₛ=±1 energy levels, splitting the energy levels ms=±1 by an amount 2 gμ_{B}B_{z}, where g is the g-factor, μ_{B} is the Bohr magneton, and B_{z} is the component of the external magnetic field along the NV axis. This relationship is correct to a first order and inclusion of higher order corrections is a matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

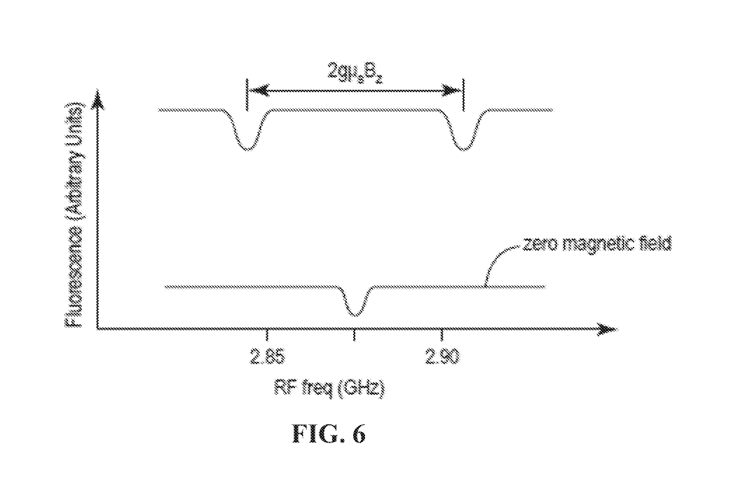

For continuous wave excitation, the optical excitation source 100 continuously pumps the defect centers, and the RF excitation source 330 sweeps across a frequency range that includes the zero splitting (when the mₛ=±1 spin states have the same energy) photon energy of 2.87 GHz. The fluorescence for an RF sweep corresponding to a magneto-optical defect center material 320 with defect centers aligned along a single direction is shown in FIG. 6 for different magnetic field components B_{z} along the detect center axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, and spin echo pulse sequence. The excitation scheme utilized during the measurement collection process (i.e., the applied optical excitation and the applied RF excitation) may be any appropriate excitation scheme. For example, the excitation scheme may utilize continuous wave (CW) magnetometry, pulsed magnetometry, and variations on CW and pulsed magnetometry (e.g., pulsed RF excitation with CW optical excitation). In cases where Ramsey pulse RF sequences are used, pulse parameters π and τ may be optimized using Rabi analysis and FID-Tau sweeps prior to the collection process, as described in, for example, U.S. patent application Ser. No. 15/003,590, which is incorporated by reference herein in its entirety.

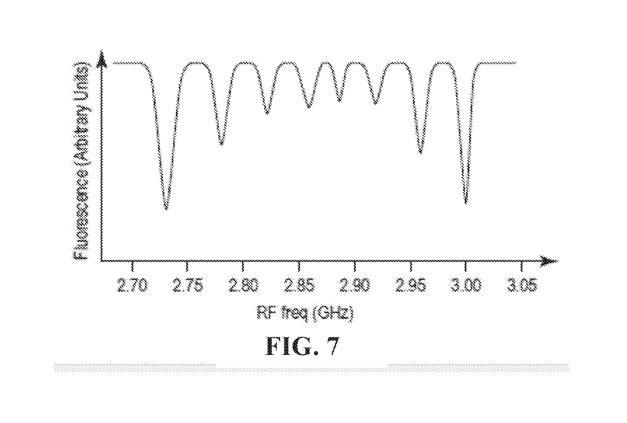

In general, the magneto-optical defect center material 320 has defect centers aligned along directions of four different orientation classes. FIG. 7 illustrates fluorescence as a function of RF frequency for the case where the magneto-optical defect center material 320 has defect centers aligned along directions of four different orientation classes. In this case, the component B_{z} along each of the different orientations may be determined. These results, along with the known orientation of crystallographic planes of a magneto-optical defect center material lattice, allow not only the magnitude of the external magnetic field to be determined, but also the direction of the magnetic field.

In general, the magnetic sensor system may employ a variety of different magneto-optical defect center material, with a variety of magneto-optical defect centers. Magneto-optical defect center materials include but are not be limited to diamonds, Silicon Carbide (SiC) and other materials with nitrogen, boron, or other defect centers. The electronic spin state energies of the magneto-optical defect centers shift with magnetic field, and the optical response, such as fluorescence, for the different spin states is not the same for all of the different spin states. In this way, the magnetic field may be determined based on optical excitation, and possibly RF excitation, in a corresponding way to that described above with NV diamond material.

In an illustrative embodiment, any of the operations described herein can be implemented at least in part as computer-readable instructions stored on a computer-readable memory. Upon execution of the computer-readable instructions by a processor, the computer-readable instructions can cause a node to perform the operations.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.” Further, unless otherwise noted, the use of the words “approximate,” “about,” “around,” “substantially,” etc., mean plus or minus ten percent.

The foregoing description of illustrative embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. An optical excitation assembly for attachment to a base structure comprising:
a defect center in a magneto-optical defect center material in a fixed position relative to the base structure;
an optical excitation source;
a slot configured to adjust the optical excitation source in a respective linear direction relative to the base structure;
a lens; and
a drive screw mechanism configured to adjust a position of the lens relative to the optical excitation source.

2. The optical excitation assembly of claim 1, further comprising:
a plurality of drive screw mechanisms configured to adjust a position of the lens relative to the optical excitation source, each of the plurality of drive screw mechanisms configured to adjust in a direction orthogonal to the other drive screw mechanisms.

3. The optical excitation assembly of claim 2, further comprising a shim
configured to adjust the optical excitation assembly in a linear direction relative to the base structure.

4. The optical excitation assembly of claim 1, wherein light from the optical excitation source is directed through the lens in to the magneto-optical defect center material with the defect center.

5. The optical excitation assembly of claim 4 further comprising:
a half-wave plate assembly comprising:
a half-wave plate,
a mounting disk adhered to the half-wave plate, and
a mounting base configured such that the mounting disk can rotate relative to the mounting base around an axis of the half-wave plate.

6. The optical excitation assembly of claim 5, wherein the lens is configured to direct light from the optical excitation source through the half-wave plate before the light is directed to the magneto-optical defect center material with the defect center.

7. The optical excitation assembly of claim 5, further comprising: a pin adhered to the mounting disk, wherein the mounting base comprises a mounting slot configured to receive the pin, wherein the pin can slide along the mounting slot and the mounting disk can rotate relative to the mounting base around the axis of the half-wave plate, the axis perpendicular to a length of the mounting slot.

8. The optical excitation assembly of claim 5, wherein the magneto-optical defect center material with the defect center comprises a nitrogen vacancy (NV) diamond material comprising a plurality of NV centers.

9. The optical excitation assembly of claim 1, further comprising: a screw lock inserted through the slot and configured to prevent relative motion of the optical excitation assembly to the base structure when tightened.

10. An assembly for attachment to a base structure comprising:
a slot configured to adjust the assembly in a respective linear direction relative to the base structure;
an optical excitation source;
a plurality of lenses; and
an adjustment mechanism configured to adjust a position of the plurality of lenses relative to the optical excitation source.

11. The assembly of claim 10, further comprising a magneto-optical defect center material with defect centers, wherein light from the optical excitation source is directed through the plurality of lenses into the magneto-optical defect center material with defect centers.

12. The assembly of claim 11, wherein the assembly is configured to direct light from the optical excitation source through a half-wave plate before the light is directed to the magneto-optical defect center material.

13. The assembly of claim 10, further comprising: a mounting disk adhered to the half-wave plate and the mounting disk is configured to rotate relative to the mounting base around an axis of the half-wave plate.

14. The assembly of claim 13, further comprising: a pin adhered to the mounting disk, wherein the mounting base comprises a mounting slot configured to receive the pin, wherein the pin can slide along the slot and the mounting disk can rotate relative to the mounting base around the axis of the half-wave plate, the axis perpendicular to a length of the slot.

15. The assembly of claim 11, wherein the magneto-optical defect center material with defect centers comprises a nitrogen vacancy (NV) diamond material comprising a plurality of NV centers.

16. The assembly of claim 13, wherein the magneto-optical defect center material with defect centers comprises a nitrogen vacancy (NV) diamond material comprising a plurality of NV centers and wherein the optical excitation source is one of a laser diode or a light emitting diode.

17. The assembly of claim 10, further comprising: a screw lock inserted through the slot and configured to prevent relative motion of the optical excitation assembly to the base structure when tightened.

18. The assembly of claim 17, further comprising: a second screw lock attached to the mounting disk, wherein the second screw lock is configured to prevent rotation of the mounting disk relative to the mounting base when tightened.

19. The assembly of claim 10, wherein the lens is configured to direct light from the optical excitation source through the half-wave plate before the light is directed to the magneto-optical defect center material.

20. A sensor assembly, comprising:
a base structure; and
an optical excitation assembly comprising:
an optical excitation means, for providing optical excitation through a plurality of lenses,
magneto-optical defect center material comprising a plurality of magneto-optical defect centers, and
an adjustment means for adjusting the location of the provided optical excitation where it reaches the magneto-optical defect center material.

21. A method of adjusting an optical excitation assembly relative to a base structure comprising:
adjusting an optical excitation source in a respective linear direction relative to the base structure using a slot;
adjusting a position of a lens in the optical excitation assembly relative to the optical excitation source using a drive screw mechanism; and
wherein, adjusting the optical excitation source and adjusting the position of a lens directs light from the optical excitation source to a defect center in a magneto-optical defect center that is in a fixed position relative to the base structure.

22. The method of claim 21 further comprising:
adjusting the position of the lens in the optical excitation assembly using a plurality of drive screw mechanisms, wherein each of the plurality of drive screw mechanisms adjusts in a direction orthogonal to the other drive screw mechanisms.

23. The method of claim 22 further comprising adjusting the optical excitation assembly in a linear direction relative to the base structure using a shim.

24. The method of claim 21, wherein the light directed from the optical excitation source to the defect center is directed through the lens.

25. The method of claim 21, further comprising:
rotating a half-wave plate attached to the optical excitation assembly around an axis of the half-wave plate using a half-wave plate assembly, wherein the half-wave plate assembly comprises a mounting disk adhered to the half-wave plate.

26. The method of claim 25, wherein the light directed from the optical excitation source to the defect center is directed through the lens and through the half-wave plate prior to reaching the defect center.

27. The method claim 25, wherein rotating the half-wave plate further comprises sliding a pin adhered to the mounting disk along a mounting slot in the mounting disk, the axis of the half-wave plate perpendicular to a length of the mounting slot.

28. The method of claim 21, wherein, wherein the magneto-optical defect center material with the defect center comprises a nitrogen vacancy (NV) diamond material comprising a plurality of NV centers.

29. The method of claim 21 further comprising tightening a screw lock inserted through the slot to prevent relative motion of the optical excitation assembly to the base structure.
